(19) United States
(12) Patent Application Publication
(10) Pub. No.: US 2023/0078325 A1
(43) Pub. Date: Mar. 16, 2023

(54) CRYSTAL PULLING SYSTEMS HAVING COMPOSITE POLYCRYSTALLINE SILICON FEED TUBES, METHODS FOR PREPARING SUCH TUBES, AND METHODS FOR FORMING A SINGLE CRYSTAL SILICON INGOT

(71) Applicant: GlobalWafers Co., Ltd., Hsinchu (TW)

(72) Inventors: Richard Joseph Phillips, St. Peters, MO (US); Salvador Zepeda, St. Peters, MO (US); William Luter, St. Charles, MO (US)

(21) Appl. No.: 17/895,694

(22) Filed: Aug. 25, 2022

Related U.S. Application Data
(60) Provisional application No. 63/244,047, filed on Sep. 14, 2021.

(51) Int. Cl. C30B 15/04; C30B 15/00; B28B 1/26; B28B 11/24; C30B 29/06

(52) U.S. Cl. CPC C30B 15/04; C30B 15/002; B28B 1/26; B28B 11/243; C30B 29/06

(57) ABSTRACT

Crystal pulling systems having composite polycrystalline silicon feed tubes, methods for forming such tubes, and methods for forming a single crystal silicon ingot with use of such tubes. The composite polycrystalline silicon feed tubes include quartz and at least one dopant. The composite polycrystalline silicon feed tube may be made by a slip cast method.

### CROSS-REFERENCE TO RELATED APPLICATION

This application claims the benefit of U.S. Provisional Patent Application No. 63/244,047, filed Sep. 14, 2021, which is incorporated herein by reference in its entirety.

### FIELD OF THE DISCLOSURE

The field of the disclosure relates to crystal pulling systems having composite polycrystalline silicon feed tubes, methods for forming such tubes, and methods for forming a single crystal silicon ingot with use of such tubes.

### BACKGROUND

In continuous Czochralski methods for forming a single crystal silicon ingot, polycrystalline silicon is continually or intermittently added to the melt to replenish the melt as the silicon ingot is pulled from the melt. In some conventional methods, solid-state polycrystalline silicon is added to the melt through a feed tube which extends through the ingot puller housing. In some batch modes for growth of a single crystal silicon ingot, the crystal puller system may remain at temperature and polycrystalline silicon is fed to the crucible to prepare a second melt of silicon from which a second ingot may be grown.

Polycrystalline silicon may abrade the feed tubes which causes impurities to enter the melt. The feed tubes are conventionally made by a fused silica process which results in the tube having uniform properties across its length. A need exists for crystal pulling systems which reduce the amount of impurities which enter the melt during addition of solid-state polycrystalline silicon and/or for methods for producing feed tubes that enable the tubes to have variable properties across its length.

This section is intended to introduce the reader to various aspects of art that may be related to various aspects of the disclosure, which are described and/or claimed below. This discussion is believed to be helpful in providing the reader with background information to facilitate a better understanding of the various aspects of the present disclosure. Accordingly, it should be understood that these statements are to be read in this light, and not as admissions of prior art.

### SUMMARY

One aspect of the present disclosure is directed to a crystal pulling system for growing a monocrystalline ingot from a silicon melt. The system includes a pull axis and includes a housing defining a growth chamber. A crucible assembly is disposed within the growth chamber for containing the silicon melt. A composite polycrystalline silicon feed tube extends through the housing into the growth chamber to feed polycrystalline silicon into the crucible assembly. The composite polycrystalline silicon feed tube is made of quartz and at least one dopant.

Another aspect of the present disclosure is directed to a method for preparing a polycrystalline silicon feed tube. A slip slurry is introduced into a mold. The slip slurry includes silica, a dopant, and a liquid carrier. At least a portion of the liquid carrier is removed from the mold to form a polycrystalline silicon feed tube green body. The polycrystalline silicon feed tube green body is separated from the mold. The polycrystalline silicon feed tube green body is sintered to dry and densify the polycrystalline silicon feed tube green body to form the polycrystalline silicon feed tube.

Yet another aspect of the present disclosure is directed to a method for forming a single crystal silicon ingot. A melt of silicon is formed in a crucible assembly. The melt of silicon is contacted with a seed crystal. The seed crystal is withdrawn from the melt to form a single crystal silicon ingot. Polycrystalline silicon is added to the melt through a composite polycrystalline silicon feed tube to replenish the melt. The composite polycrystalline silicon feed tube includes quartz and a dopant.

Various refinements exist of the features noted in relation to the above-mentioned aspects of the present disclosure. Further features may also be incorporated in the above-mentioned aspects of the present disclosure as well. These refinements and additional features may exist individually or in any combination. For instance, various features discussed below in relation to any of the illustrated embodiments of the present disclosure may be incorporated into any of the above-described aspects of the present disclosure, alone or in any combination.

### BRIEF DESCRIPTION OF THE DRAWINGS

FIG. 1 is a cross-section view of a crystal pulling system for growing a monocrystalline ingot from a silicon melt;

FIG. 2 is a detailed cross-section view of the crystal pulling system; and

FIG. 3 is a graph showing change in thermal conductivity with increasing amount of Si or AlN dopant in the silicon feed tube.

Corresponding reference characters indicate corresponding parts throughout the drawings.

### DETAILED DESCRIPTION

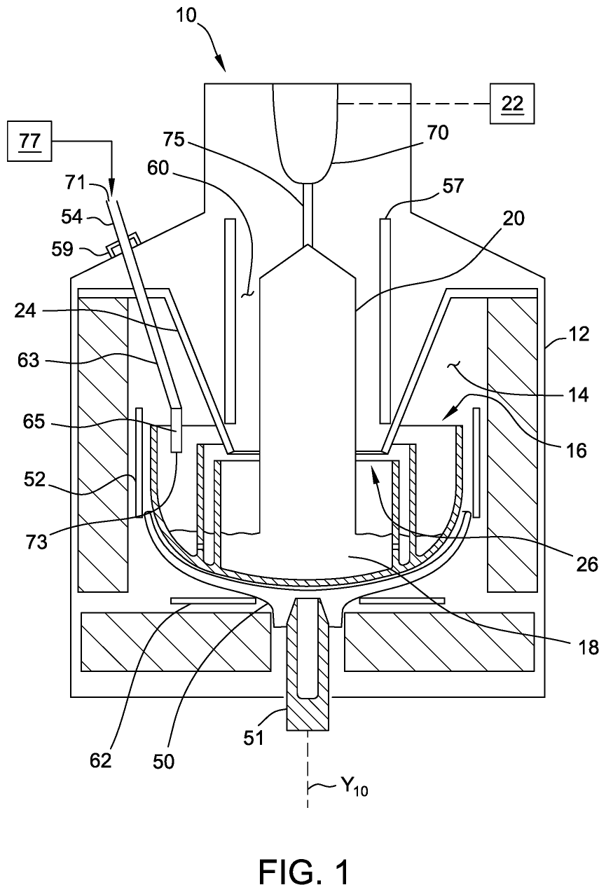

Provisions of the present disclosure relate to crystal pulling systems for producing monocrystalline (i.e., single crystal) silicon ingots (e.g., semiconductor or solar-grade material) from a silicon melt by the continuous Czochralski (CZ) method. The systems and methods disclosed herein may also be used to grow monocrystalline ingots by a batch or recharge CZ method. With reference to FIG. 1, an example crystal pulling system is shown schematically and is indicated generally at 10. The crystal pulling system 10 includes a pull axis Y₁₀ and a housing 12 defining a growth chamber 14. A crucible assembly 16 is disposed within the growth chamber 14. The crucible assembly 16 contains the silicon melt 18 (e.g., semiconductor or solar-grade material) from which a monocrystalline ingot 20 is pulled by a pulling mechanism 22 as discussed further below. The crystal pulling system 10 includes a heat shield 24 (sometimes referred to as a “reflector”) that defines a central passage 26 through which the ingot 20 passes during ingot growth.

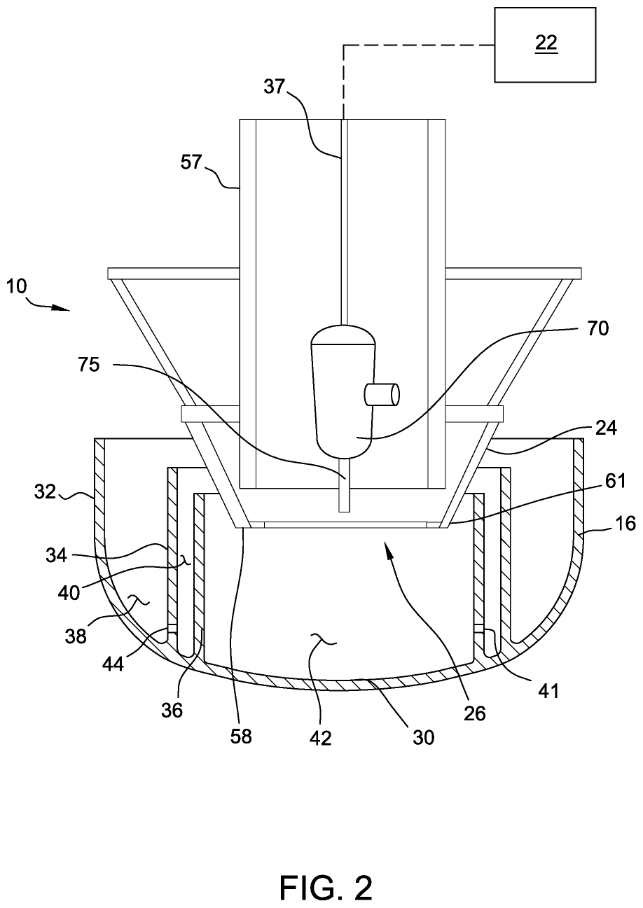

FIG. 2 shows a portion of the crystal pulling system 10 prior to the ingot 20 being drawn. The crucible assembly 16 includes a bottom 30 and an outer sidewall 32 that extends upwards from the bottom 30. The crucible assembly 16 includes a central weir 34 and an inner weir 36 that extends upward from the bottom 30. The central weir 34 is disposed between the outer sidewall 32 and the inner weir 36. The crucible assembly 16 includes a crucible melt zone 38 disposed between the outer sidewall 32 and the central weir 34. The crucible assembly 16 also contains an intermediate zone 40 disposed between the central weir 34 and the inner weir 36. The crucible assembly 16 also contains a growth zone 42 disposed within the inner weir 36. The crucible assembly 16 may be made of, for example, quartz or any other suitable material that enables the crystal pulling system 10 to function as described herein. Further, the crucible assembly 16 may have any suitable size that enables the crystal pulling system 10 to function as described herein. The crucible assembly 16 may also include three “nested” crucibles which have separate bottoms that together make a bottom and in which the sidewalls of the crucibles are the weirs 34, 36 described above. In other embodiments (e.g., batch recharge systems), the crucible does not include weirs within the crucible outer sidewall 32.

During ingot growth, polycrystalline silicon is added to the crucible melt zone 38 where the silicon melts and replenishes the silicon melt. Silicon melt flows through a central weir opening 44 and into the intermediate zone 40. The silicon melt then flows through an inner weir opening 41 to the growth zone 42 disposed within the inner weir 36. The various silicon melt zones (e.g., outer melt zone 38, intermediate zone 40 and growth zone 42) allow the ingot to be grown in accordance with continuous Czochralski methods in which polycrystalline silicon is continuously or semi-continuously added to the melt while an ingot 20 is continuously pulled from the growth zone 42. The silicon melt 18 within the growth zone 42 is contacted with a single seed crystal 75 (FIG. 1). The crystal 75 is held by a chuck 70 which is connected to a pull wire or cable 37. The pull wire 37, chuck 70 and seed crystal 75 are raised and lowered by a pulling mechanism 22 (e.g., powered roller, pulley, or spool). As the seed crystal 75 is slowly raised from the melt 18, atoms from the melt 18 align themselves with and attach to the seed 75 to form the ingot 20.

The crucible assembly 16 is supported by a susceptor 50 (FIG. 1). The susceptor 50 is supported by a rotatable shaft 51. A side heater 52 surrounds the susceptor 50 and crucible assembly 16 for supplying thermal energy to the system 10. One or more bottom heaters 62 are disposed below the crucible assembly 16 and susceptor 50. The heaters 52, 62 operate to melt an initial charge of solid polycrystalline silicon feedstock, and maintain the melt 18 in a liquefied state after the initial charge is melted. The heaters 52, 62 also act to melt solid polycrystalline silicon added through a polysilicon feed tube 54 (FIG. 1) during growth of the ingot. The heaters 52, 62 may be any suitable heaters that enable to system 10 to function as described herein (e.g., resistance heaters).

The crystal pulling system 10 includes a gas inlet (not shown) for introducing an inert gas into the growth chamber 14, and one or more exhaust outlets (not shown) for discharging the inert gas and other gaseous and airborne particles from the growth chamber 14. The gas inlet supplies suitable inert gases such as argon.

The system 10 includes a cylindrical jacket 57 disposed with the heat shield 24. The jacket 57 is fluid-cooled and includes a jacket chamber 60 that is aligned with the central passage 26. The ingot 20 is drawn along the pull axis Y₁₀, through the central passage 26 and into the jacket chamber 60. The jacket 57 cools the drawn ingot 20.

The heat shield 24 is generally frustoconical in shape. The heat shield 24 includes an outer surface 61 which faces the crucible assembly 16 and the melt 18. The heat shield 24 may be coated to prevent contamination of the melt. In some embodiments, the heat shield 24 is made of two graphite shells that include molybdenum sheets therein. The surface 61 may be coated (e.g., SiC) to reduce contamination of the melt.

The heat shield 24 includes a bottom 58 (FIG. 2). The heat shield 24 is disposed above the crucible assembly 16, such that the central passage 26 is arranged directly above the growth zone 42 so that the ingot drawn from the melt 18 may be pulled through the central passage 26. The outer surface 61 may be coated with a reflective coating which reflects radiant heat back towards the melt 18 and the crucible assembly 16. As such, the heat shield 24 assists in retaining heat within the crucible assembly 16 and the melt 18. In addition, the heat shield 24 aids in maintaining a generally uniform temperature gradient along the pull axis Y₁₀.

During the initial melting phase, an initial amount of solid polycrystalline silicon is loaded to a crucible melt zone 38, intermediate zone 40 and growth zone 42. The initial charge may be between about 10 kilograms and about 200 kilograms of silicon. The mass of the initial charges depends on the desired crystal diameter and hot zone design.

The initial charge of solid-state silicon is melted and the ingot 20 is pulled from the melt 18. During ingot growth (or after as in a batch re-charge system), solid-state polysilicon is added to the crucible assembly 16 through the polycrystalline silicon feed tube 54 (or simply “feed tube”) which extends through the crystal puller housing 12 and into the growth chamber 14. The polycrystalline feed tube 54 includes an inlet 71 that is external the crystal puller apparatus housing 12. Solid-state polycrystalline silicon may be added to the tube 54 through the inlet 71 by a dopant feed system 77. Generally, any suitable dopant feed system 77 that allows the crystal puller system 10 to operate as described herein is suitable unless stated differently. Example dopant feed systems 77 may include a storage vessel and a vibratory chute (e.g., a chute with a vibrator connected to the chute). The vibratory chute moves solid-state polycrystalline silicon from the storage vessel to the inlet of the tube 54.

The polycrystalline feed tube 54 includes an outlet 73 within the growth chamber 14. Solid-state silicon falls through the tube 54 and is discharged from the tube 54 through the outlet 73. The outlet 73 may be disposed within the crucible assembly 16 (e.g., below a top of the crucible assembly 16) such as within the outer melt zone 38.

The polycrystalline silicon feed tube 54 is positioned in a polycrystalline silicon feed tube port 59 formed in the housing 12 of the crystal pulling system 10 (i.e., one the polycrystalline silicon feed tube 54 is formed such as by the slip cast method described below).

Solid-state silicon fed through the feed tube 54 may be, for example, polysilicon chips, granular polysilicon, or chunk polysilicon, or a combination thereof. Chunk polysilicon is generally larger in size than chip polysilicon which is larger in size than granular polysilicon. For example, chunk polysilicon may generally have an average nominal size of at least 15 mm (e.g., ranging from 5 mm to 110 mm) while chip polysilicon may have an average nominal size from 1 to 15 mm. The solid-state silicon is added at a rate sufficient to maintain a substantially constant melt elevation level and volume during growth of the ingot 20.

In accordance with embodiments of the present disclosure, at least a portion of the polycrystalline silicon feed tube 54 is a composite material. The composite tube 54 is made of a base material (e.g., quartz) and at least one dopant (sometimes referred to herein as “second phase”). Generally, any suitable dopant may be used (e.g., a dopant that modifies or enhances the properties of the feed tube 54).

Suitable dopants include, for example, SiC, Si₃N₄, AlN, Si, ZrO₂ or Y₂O₃, and combinations thereof. The concentration of dopant in the composite feed tube 54 may be any suitable range which allows the feed tube 54 and crystal pulling system 10 to operate as described herein. In some embodiments, the concentration of the dopant in the tube 54 is at least 20 ppm, at least 50 ppm, or at least 100 ppm (e.g., between 20 ppm and 10,000 ppm or from 100 ppm to 10,000 ppm). Some mixed phases may have even higher concentrations of the second phase dopant (e.g., at least 30 vol % of second phase, at least 40 vol %, at least 50%, or at least 60 vol % or more of second phase).

In some embodiments, the entire tube 54 is formed of a composite material (e.g., quartz and at least one second phase dispersed through the quartz). In other embodiments, only a portion of the tube 54 is made of a composite material. For example, the upper segment 63 of the tube 54 that extends through the housing 12 may be made of a composite material or the bottom segment 65 that extends vertically downward from the upper segment 63 and into the crucible assembly 16 may be made of a composite material. Various segments of the tube 54 may be made of a composite but with different concentration or types of dopants in one or more of the segments. The tube 54 illustrated in FIG. 1 is an example tube and the tube 54 may have different configurations (e.g., more or less sections).

The composite tube 54 may be formed by a slip cast process. As described further below, a slip slurry (or simply “slip”) is poured into a mold and a “green body” in the shape of the tube 54 is formed. The green body is removed from the mold and is sintered to form the tube 54. The mold is typically shaped as a negative shape of the tube (e.g., having an outer portion and an inner core which forms a cylindrical gap which may be filled with slip slurry). The mold may be made of two segments which are separable.

In some embodiments, the slip slurry that is added to the channels within the mold includes silica (SiO₂), the at least one dopant, and a liquid carrier such as water. The slip slurry may also include other reagents such as suspending agents that keep the silica particles in suspension including any of the suspending agents known to those of skill in the art. Example suspending agents include polymers or organics that absorb onto the particles (e.g., long-chain organic molecules or other agents that allow a surface charge to build-up on the silica particles to reduce particle to particle contact). The slip slurry may also include one or more binding agents that may optionally burn off during sintering as described below. Optionally the slip slurry may include one or more release agents to promote separation of the tube mold from the resulting green body.

The tube mold may be made of materials that allow the liquid carrier to be removed from the mold (e.g., such as by capillary action) to form the green body. In some embodiments, the tube mold is made of a plaster such as gypsum plaster (e.g., CaSO₄.nH₂O which may also be referred to as plaster of Paris). In other embodiments, the tube mold is made of porous silica. The tube mold may be a generally porous body that draws the liquid carrier into the mold by capillary action. In other embodiments, the liquid carrier may be drawn out by vacuum.

Once the liquid carrier is drawn out of the slip slurry and into the mold, a “green body” remains in the mold. For example, the green body may have sufficient structure to maintain its shape when separated from the mold. For example, the moisture content of the green body may be less than about 50%, less than about 45%, at least about 30 wt %, at least about 35 wt %, at least about 40 wt %, at least about 45 wt %, from about 30 wt % to about 50 wt % or from about 35 wt % to about 45 wt %.

The green body may be further dried such as by exposing the green body to a relatively low and/or controlled humidity ambient (e.g., after the green body has sufficient strength, the mold is removed and the green body is exposed to the relatively low and/or controlled humidity ambient). The term “green body” or “green state” as used herein should not be considered in a limiting sense and generally refers to an intermediate state of the tube after the liquid carrier has been partially drawn from the slip slurry and before sintering of the structure.

The green body may include projections (i.e., projections used to form the shape of the mold components) that may be ground or cut from the green body or the resulting polycrystalline silicon feed tube 54 (FIG. 1).

Once the polycrystalline silicon tube green body is removed from the mold, the green body may be sintered (e.g., in a drying furnace) to dry and densify the green body and to form the polycrystalline feed tube 54 (FIG. 1). The green body may be sintered at a temperature from about 1200° C. to about 1800° C., from about 1300° C. to about 1700° C., or from about 1300° C. to about 1650° C. In some embodiments, the polycrystalline tube has a moisture content of less than 20 wt %, less than 15 wt %, less than 10 wt % or less than 5 wt % after sintering.

Other methods for forming the tube 54 may be used. For example, in other embodiments, the tube 54 may be made by a 3D printing method. In other embodiments, tape casting or extrusion is used. While the tube 54 has been shown and described as a cylinder, the tube 54 may also have other symmetric or asymmetric shapes. For example, the tube 54 may have a trough shape.

The methods of the present disclosure for forming a composite polycrystalline feed tube made of quartz and at least one dopant may be used to produce a single crystal silicon ingot. In such methods, polycrystalline silicon is added to the crucible assembly 16 by adding polycrystalline silicon to the composite tube 54. The tube is made of quartz and at least one dopant.

Compared to conventional polycrystalline silicon feed tubes, the feed tubes of the present disclosure have several advantages. Use of a second phase (i.e., one or more dopants) within the tube (e.g., quartz tube) reduces wear and abrasion caused by solid-state silicon contacting the tube as it travels down the tube to the crucible assembly. This reduces the amount of impurities (e.g., oxygen and other impurities present in the silica used to form the tube). Use of the dopant also reduces the incidence of occlusions of polycrystalline silicon that form in the tube. Use of dopant also allows the thermal conductivity of the tube to be varied and/or allows the opacity of the tube to be varied. Thermal conductivity and opacity variation allows polysilicon melting on the walls of the tube to be reduced and/or dust collection and clogging to be reduced. Use of slip cast methods for forming the tube (e.g., as opposed to fused silicon methods) allows dopants to be incorporated into the tube and allows the tube to be formed in non-symmetric shapes. Non-symmetric designs allow wear and rebound effects to be reduced, thereby lowering the impurity concentration in the feeding system. Slip cast methods also allow for certain portions of the tube to be tailored to specific dopant levels such as to vary the thermal conductivity or opacity at the particular region of the tube. In embodiments in which the tube is made by slip casting, the method may result in a net shape near the final dimensions of the tube and/or a ready-for-service tube (with machining being reduced or eliminated).

### EXAMPLES

The processes of the present disclosure are further illustrated by the following Examples. These Examples should not be viewed in a limiting sense.

### Example 1: Variation of Thermal Conductivity in Slip Cast Tubes Having Different Dopants

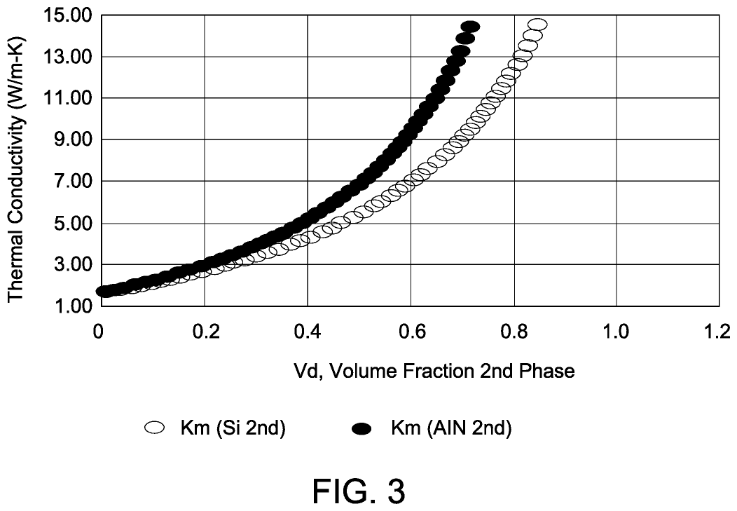

The amount of dopant (silicon or AlN) in a quartz polycrystalline tube may be varied to change the thermal conductivity of the tube. FIG. 3 shows the change of thermal conductivity as a function of dopant concentration. For example, 20-30 volume percent of dopant can be added to change the thermal conductivity from that of quartz (about 1.8 W/m*K) to about 3 W/m*K.

As used herein, the terms “about,” “substantially,” “essentially” and “approximately” when used in conjunction with ranges of dimensions, concentrations, temperatures or other physical or chemical properties or characteristics is meant to cover variations that may exist in the upper and/or lower limits of the ranges of the properties or characteristics, including, for example, variations resulting from rounding, measurement methodology or other statistical variation.

When introducing elements of the present disclosure or the embodiment(s) thereof, the articles “a,” “an,” “the,” and “said” are intended to mean that there are one or more of the elements. The terms “comprising,” “including,” “containing,” and “having” are intended to be inclusive and mean that there may be additional elements other than the listed elements. The use of terms indicating a particular orientation (e.g., “top,” “bottom,” “side,” etc.) is for convenience of description and does not require any particular orientation of the item described.

As various changes could be made in the above constructions and methods without departing from the scope of the disclosure, it is intended that all matter contained in the above description and shown in the accompanying drawing[s] shall be interpreted as illustrative and not in a limiting sense.

What is claimed is:

1. A crystal pulling system for growing a monocrystalline ingot from a silicon melt, the system having a pull axis and comprising:
a housing defining a growth chamber;
a crucible assembly disposed within the growth chamber for containing the silicon melt; and
a composite polycrystalline silicon feed tube that extends through the housing into the growth chamber to feed polycrystalline silicon into the crucible assembly, the composite polycrystalline silicon feed tube being made of quartz and at least one dopant.

2. The crystal pulling system as set forth in claim 1 wherein the dopant is selected from SiC, Si₃N₄, AlN, Si, ZrO₂ and Y₂O₃.

3. The crystal pulling system as set forth in claim 1 wherein the concentration of dopant is at least 20 ppm.

4. The crystal pulling system as set forth in claim 1 wherein the concentration of dopant is at least 100 ppm.

5. The crystal pulling system as set forth in claim 1 wherein the concentration of dopant is from 100 ppm to 10,000 ppm.

6. The crystal pulling system as set forth in claim 1 wherein the composite polycrystalline silicon feed tube is made by:
introducing a slip slurry into a mold, the slip slurry comprising silica, a dopant, and a liquid carrier;
removing at least a portion of the liquid carrier from the mold to form a polycrystalline silicon feed tube green body;
separating the polycrystalline silicon feed tube green body from the mold; and
sintering the polycrystalline silicon feed tube green body to dry and densify the polycrystalline silicon feed tube green body to form the composite polycrystalline silicon feed tube.

7. A method for preparing a polycrystalline silicon feed tube, the method comprising:
introducing a slip slurry into a mold, the slip slurry comprising silica, a dopant, and a liquid carrier;
removing at least a portion of the liquid carrier from the mold to form a polycrystalline silicon feed tube green body;
separating the polycrystalline silicon feed tube green body from the mold; and
sintering the polycrystalline silicon feed tube green body to dry and densify the polycrystalline silicon feed tube green body to form the polycrystalline silicon feed tube.

8. The method as set forth in claim 7 comprising positioning the polycrystalline silicon feed tube in a polycrystalline silicon feed tube port formed in a housing of a crystal pulling system.

9. A method for forming a single crystal silicon ingot comprising:
forming a melt of silicon in a crucible assembly;
contacting the melt of silicon with a seed crystal;
withdrawing the seed crystal from the melt to form a single crystal silicon ingot; and
adding polycrystalline silicon to the melt through a composite polycrystalline silicon feed tube to replenish the melt, the composite polycrystalline silicon feed tube comprising quartz and a dopant.

10. The method as set forth in claim 9 wherein the dopant is selected from SiC, Si₃N₄, AlN, Si, ZrO₂ and Y₂O₃.

11. The method as set forth in claim 9 wherein the concentration of dopant is at least 20 ppm.

12. The method as set forth in claim 9 wherein the concentration of dopant is at least 100 ppm.

13. The method as set forth in claim 9 wherein the concentration of dopant is from 100 ppm to 10,000 ppm.

14. The method as set forth in claim 9 wherein the polycrystalline silicon feed tube is made by:
introducing a slip slurry into a mold, the slip slurry comprising silica, a dopant, and a liquid carrier;
removing at least a portion of the liquid carrier from the mold to form a polycrystalline silicon feed tube green body;
separating the polycrystalline silicon feed tube green body from the mold; and
sintering the polycrystalline silicon feed tube green body to dry and densify the polycrystalline silicon feed tube green body to form the composite polycrystalline silicon feed tube.
